(19) United States
(12) Patent Application Publication
(10) Pub. No.: US 2026/0305178 A1
(43) Pub. Date: Oct. 1, 2026

(54) Method for Manufacturing Memory Chip and Memory Chip Structure

(71) Applicant: ZHEJIANG HIKSTOR TECHNOLOGY CO., LTD., Hangzhou, Zhejiang (CN)

(72) Inventors: Zhimeng YU, Hangzhou, Zhejiang (CN); Guilin CHEN, Hangzhou, Zhejiang (CN); Yarong YU, Hangzhou, Zhejiang (CN); Shikun HE, Hangzhou, Zhejiang (CN)

(21) Appl. No.: 19/163,327

(22) PCT Filed: Mar. 6, 2024
(86) PCT No.: PCT/CN2024/080356

§ 371 Date: Sep. 8, 2025

(30) Foreign Application Priority Data
Mar. 6, 2023 (CN) 202310228968.9

(51) Int. Cl. H10N 50/01; H10B 61/00; H10B 63/00; H10N 70/00

(52) U.S. Cl. CPC H10N 50/01; H10B 61/10; H10B 63/00; H10N 70/011

(57) ABSTRACT

Disclosed are a method for manufacturing a memory chip and a memory chip structure. The method includes: a surface of a pattern transfer layer in a structure to be etched is etched, so as to form a channel; the pattern transfer layer at an opening of the channel is etched, so as to obtain a widened pattern transfer layer channel; a region to be widened in the bottom electrode dielectric layer is etched along the widened pattern transfer layer channel, so as to obtain a bottom electrode via structure which extends to a bottom circuit; the bottom electrode via structure is filled with a bottom electrode material, so as to obtain a final bottom electrode structure; and a memory cell and a top circuit structure is manufactured on a surface of the final bottom electrode structure facing away from the bottom circuit.

### CROSS-REFERENCE TO RELATED APPLICATION

This disclosure claims priority to Chinese Patent Application No. 202310228968.9, filed to the China National Intellectual Property Administration on Mar. 6, 2023 and entitled “Method for Manufacturing Memory Chip and Memory Chip Structure”, the disclosure of which is hereby incorporated by reference in its entirety.

### TECHNICAL FIELD

The present disclosure relates to the field of memory chips, and in particular, to a method for manufacturing a memory chip and a memory chip structure.

### BACKGROUND

Interiors of memory chips may usually be classified into memory array regions for realizing storage functions and logical regions for realizing logical and other functions. Memory cells are sandwiched between upper and lower metal layers, such as a Magnetic Random Access Memory (MRAM) and a Resistive Random Access Memory (RRAM). Taking the MRAM as an example, an ion beam etching is widely used to etch memory cells of the MRAM, and another ion beam over etching is applied to ensure thoroughly removing the residue after main etching. The MRAM is interconnected with a lower conductive layer through a bottom electrode. Sufficient over-etching and sidewall cleaning are essential to maintain the device performance and yield. If the bottom electrode has an insufficient height, a lower metal connecting line may be etched, resulting in metal pollution and posing a risk of reduced reliability, thereby limiting an over-etching process and a sidewall cleaning process.

Therefore, a bottom electrode with a high aspect ratio is used in the related art, but due to selectivity of a Chemical Mechanical Polishing (CMP) process, there is a significant height difference between metal in a via and the surrounding dielectric materials, which affects the device performance. To minimize the step height, it is necessary to deposit a buffer metal followed by planarization. However, the excessive area of the buffer layer compared with array area may cause unnecessary metal re-deposition and affect the device performance. At the same time, the process of depositing the buffer layer and performing planarization is complicated, which increases the cost of device manufacturing.

### SUMMARY

In view of this, an objective of the present disclosure is to provide a method for manufacturing a memory chip and a memory chip structure, which solve the problem in the related art of unnecessary metal re-deposition caused by an excessive area of a buffer layer.

In order to solve the above technical problem, the present disclosure provides a method for manufacturing a memory chip, which includes:
a surface of a pattern transfer layer in a structure to be etched is etched, so as to form a channel, where the channel extends to a bottom electrode dielectric layer in the structure to be etched, and the structure to be etched is a structure formed by sequential deposition of the bottom electrode dielectric layer and the pattern transfer layer on a surface of a bottom circuit; the pattern transfer layer at an opening of the channel is etched, so as to obtain a widened pattern transfer layer channel;
a region to be widened in the bottom electrode dielectric layer is etched along the widened pattern transfer layer channel, so as to obtain a bottom electrode via structure which extends to the bottom circuit, where a depth of the region to be widened is less than a thickness of the bottom electrode dielectric layer;
the bottom electrode via structure is filled with a bottom electrode material, so as to obtain a final bottom electrode structure;
a memory cell and a top circuit structure are manufactured on a surface of the final bottom electrode structure facing away from the bottom circuit, so as to obtain the memory chip.

In some embodiments, a depth of the channel extending to the bottom electrode dielectric layer is less than the thickness of the bottom electrode dielectric layer.

In some embodiments, the region to be widened in the bottom electrode dielectric layer is etched along the widened pattern transfer layer channel, so as to obtain the bottom electrode via structure which extends to the bottom circuit includes: the region to be widened in the bottom electrode dielectric layer and the bottom of the channel are simultaneously etched along the widened pattern transfer layer channel until the channel extends to the bottom circuit, so as to obtain the bottom electrode via structure.

In some embodiments, the surface of the pattern transfer layer in the structure to be etched is etched, so as to form a channel includes:
a photoresist layer containing a lithographic channel is manufactured on the pattern transfer layer; and
the surface of the pattern transfer layer is etched along the lithographic channel to obtain the channel.

In some embodiments, the pattern transfer layer is etched at the opening of the channel, so as to obtain the widened pattern transfer layer channel includes:
the pattern transfer layer at the opening of the channel is isotropically etched, so as to obtain the widened pattern transfer layer channel.

In some embodiments, the pattern transfer layer at the opening of the channel is isotropically etched, so as to obtain the widened pattern transfer layer channel includes:
the pattern transfer layer at the opening of the channel is isotropically etched until a first cross-sectional area of the widened pattern transfer layer channel is greater than a second cross-sectional area of the memory cell, and a difference between the first cross-sectional area and the second cross-sectional area reaches an area threshold, so as to obtain the widened pattern transfer layer channel.

In some embodiments, the depth of the region to be widened in the bottom electrode dielectric layer is less than an over etching dielectric loss of the memory cell.

In some embodiments, before the surface of the pattern transfer layer in the structure to be etched is etched, so as to form the channel, the method further includes:
a bottom electrode dielectric and a pattern transfer layer material are sequentially deposited on the surface of the bottom circuit, so as to obtain the bottom electrode dielectric layer and the pattern transfer layer;
a structure composed of the bottom circuit, the bottom electrode dielectric layer, and the pattern transfer layer is used as the structure to be etched.

The present disclosure further provides a memory chip structure, manufactured using the above method for manufacturing the memory chip, where the memory chip structure includes:
the bottom circuit, the bottom electrode dielectric layer, the final bottom electrode structure, the memory cell, and the top circuit structure;
where the final bottom electrode structure includes a widened part and a non-widened part, the non-widened part is connected to the bottom circuit, and the widened part is connected to the memory cell.

In some embodiments, a first cross-sectional area of the widened part is greater than a second cross-sectional area of the memory cell.

It can be seen that, in the method for manufacturing the memory chip provided by the present disclosure, the surface of the pattern transfer layer in the structure to be etched is etched, so as to form the channel, where the channel extends to the bottom electrode dielectric layer in the structure to be etched, and the structure to be etched is the structure formed by sequential deposition of dielectric layer and the pattern transfer layer on the surface o bottom circuit; the pattern transfer layer at the opening of the channel is etched, so as to obtain the widened pattern transfer layer channel; the region to be widened in the bottom electrode dielectric layer is etched along the widened pattern transfer layer channel, so as to obtain the bottom electrode via structure which extends to the bottom circuit, where the depth of the region to be widened is less than the thickness of the bottom electrode dielectric layer; the bottom electrode via structure is filled with the bottom electrode material, so as to obtain the final bottom electrode structure; and the memory cell and the top circuit structure are manufactured on the surface of the final bottom electrode structure facing away from the bottom circuit, so as to obtain the memory chip. In the present disclosure, an electrode structure including the widened part and the non-widened part is manufactured, and the widened part of the final bottom electrode structure is connected to the memory cell, so that the problem of the excessive area of the buffer layer caused by the buffer layer, which results in unnecessary metal re-deposition and affects the device performance, can be avoided, the complexity of a device manufacturing process is reduced, and the cost of device manufacturing is reduced.

In addition, the present disclosure further discloses a memory chip structure, which also has the above beneficial effects.

### BRIEF DESCRIPTION OF THE DRAWINGS

In order to more clearly illustrate the embodiments of the present disclosure or the technical solutions in the related art, the drawings used in the description of the embodiments or the related art will be briefly described below. It is apparent that the drawings described below are only embodiments of the present disclosure. Other drawings may further be obtained by those of ordinary skill in the art according to these drawings without creative efforts.

FIG. 1 is a flowchart of a method for manufacturing a memory chip according to an embodiment of the present disclosure.

FIG. 2 is a schematic diagram of a memory chip structure according to an embodiment of the present disclosure.

FIG. 3 is a schematic structure of step S1 of a method for manufacturing a memory chip according to an embodiment of the present disclosure.

FIG. 4 is a schematic structure of step S2 of a method for manufacturing a memory chip Substitute Specification-Clean according to an embodiment of the present disclosure.

FIG. 5 is a schematic structure of step S3 of a method for manufacturing a memory chip according to an embodiment of the present disclosure.

FIG. 6 is a schematic structure of step S4 of a method for manufacturing a memory chip according to an embodiment of the present disclosure.

FIG. 7 is a schematic structure of step S5 of a method for manufacturing a memory chip according to an embodiment of the present disclosure.

10-Bottom circuit,
11-Bottom circuit diffusion barrier layer;
20-Bottom electrode dielectric layer;
30-Final bottom electrode structure;
40-Memory cell,
41-Memory cell protection layer;
50-Top circuit structure;
60-Pattern transfer layer;
70-Photoresist layer.

### DETAILED DESCRIPTION OF THE EMBODIMENTS

In order to make the objectives, technical solutions, and advantages of the embodiments of the present disclosure clearer, the technical solutions in the embodiments of the present disclosure will be clearly and completely described in conjunction with the drawings in the embodiments of the present disclosure. It is apparent that the described embodiments are only a part of the embodiments of the present disclosure, and not all of them. All other embodiments obtained by those of ordinary skill in the art on the basis of the embodiments in the present disclosure without creative work shall fall within the scope of protection of the present disclosure.

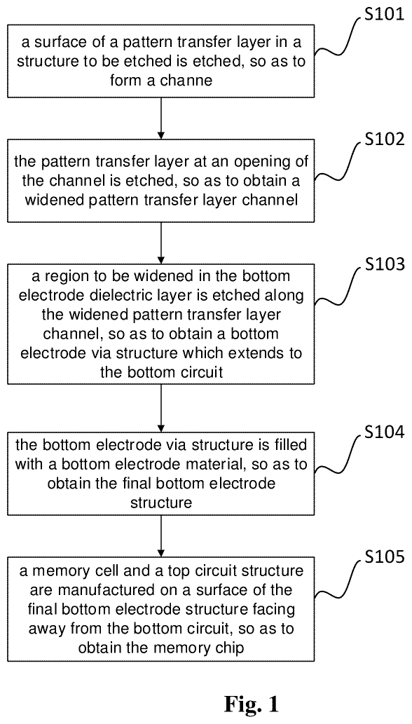

Referring to FIG. 1, FIG. 1 is a flowchart of a method for manufacturing a memory chip according to an embodiment of the present disclosure. The method may include the following operations.

At S101, a surface of a pattern transfer layer in a structure to be etched is etched, so as to form a channel.

An execution subject of the present embodiment is a manufacturing device. It is to be noted that, in the present embodiment, the channel extends to a bottom electrode dielectric layer in the structure to be etched, and the structure to be etched is a structure formed by sequential deposition of the bottom electrode dielectric layer and the pattern transfer layer on a surface a bottom circuit. A depth of the channel extending to the bottom electrode dielectric layer in the structure to be etched is not limited in the present embodiment, as long as the shape of the channel can be transferred to the bottom electrode dielectric layer. For example, the channel may extend to the bottom electrode dielectric layer and pass through the entire bottom electrode dielectric layer, that is, the channel extends to the bottom of the bottom electrode dielectric layer; or the channel may extend to a part of the bottom electrode dielectric layer, that is, the channel does not pass through the entire bottom electrode dielectric layer.

Furthermore, in order to ensure that the surface of the bottom circuit is not contaminated in the etching process, the depth of the above channel which extends to the bottom electrode dielectric layer may be less than a thickness of the bottom electrode dielectric layer.

It is to be noted that, in the present embodiment, the channel extends to a part of the bottom electrode dielectric layer, and does not pass through the entire bottom electrode dielectric layer. After widening treatment is performed at an opening of the channel of the pattern transfer layer and a widened pattern transfer layer channel is transferred to the bottom electrode dielectric layer, etching of the bottom of the channel of the bottom electrode dielectric layer is performed until the bottom circuit is exposed at the bottom of the channel.

The timing for initiating the operation of etching the bottom of the channel of the bottom electrode dielectric layer and the exposure of bottom circuit at the bottom of the channel is not limited in the present embodiment, as long as the structure of the bottom circuit is exposed at the bottom of the channel. For example, the operation of etching the bottom of the channel of the bottom electrode dielectric layer to expose the bottom circuit may be completed simultaneously with the step of transferring the widened pattern transfer layer channel to the bottom electrode dielectric layer; or in the present embodiment, the operation of etching the bottom of the channel of the bottom electrode dielectric layer to expose bottom circuit at the bottom of the channel may be performed after the step of transferring the widened pattern transfer layer channel to the bottom electrode dielectric layer.

In some embodiments, in order to improve the efficiency of memory chip manufacturing and reduce the time cost of etching, the method may include:
the region to be widened in the bottom electrode dielectric layer and a bottom of the channel are simultaneously etched along the widened pattern transfer layer channel until exposure of the bottom circuit, so as to obtain a bottom electrode via structure.

It is to be noted that, in the present embodiment, etching of the bottom of the channel of the bottom electrode dielectric layer is completed simultaneously with the step of transferring the widened pattern transfer layer channel to the bottom electrode dielectric layer.

In some embodiments, in order to improve the efficiency of etching the channel and simplify the steps of etching the channel, the above operations that the etching of the surface of the pattern transfer layer in the structure to be etched to form the channel may include:
a photoresist layer containing a lithographic channel is manufactured on the pattern transfer layer;
and the channel is etched on the surface of the pattern transfer layer along the lithographic channel.

It is to be noted that, in the present embodiment, the step of etching the surface of the pattern transfer layer in the structure to be etched, so as to form the channel is completed by etching of the surface of the pattern transfer layer along the lithographic channel. After the above operation that the channel is etched on the surface of the pattern transfer layer along the lithographic channel, the above photoresist layer needs to be completely removed.

In some embodiments, in order to fabricate the memory chip in the present embodiment, before the surface of the pattern transfer layer in the structure to be etched is etched, to form the channel, the method may further include:
a bottom electrode dielectric and a pattern transfer layer material are sequentially deposited on the surface of the bottom circuit
and a structure composed of the bottom circuit, the bottom electrode dielectric layer, and the pattern transfer layer is used as the structure to be etched.

It is to be noted that, in the present embodiment, the structure to be etched may be obtained by sequentially depositing the bottom electrode dielectric and the pattern transfer layer material on the surface of the bottom circuit.

In some embodiments, in order to ensure the cleanliness of the bottom circuit, a bottom circuit diffusion barrier layer may be provided on the surface of the bottom circuit.

At S102, the pattern transfer layer at an opening of the channel is etched, so as to obtain a widened pattern transfer layer channel.

In the present embodiment, etching is performed at the opening of the channel of the pattern transfer layer, and widening treatment is performed on the channel in the pattern transfer layer, so as to obtain the widened pattern transfer layer channel. The specific operation of performing etching at the opening of the channel of the pattern transfer layer is not limited in the present embodiment, as long as the widened pattern transfer layer channel can be obtained. For example, etching may be performed at the opening of the channel of the pattern transfer layer using an isotropic etching operation, so as to obtain the widened pattern transfer layer channel; or lateral etching may be performed on the pattern transfer layer with respect to the opening of the channel, so as to obtain the widened pattern transfer layer channel, or certain part of the pattern transfer layer may be covered with a photoresist, and etching is performed at the opening of the channel exposing the pattern transfer layer, so as to obtain the widened pattern transfer layer channel.

In some embodiments, in order to improve the efficiency of widening the channel at the pattern transfer layer, the above operation that the pattern transfer layer is etched to obtain the widened pattern transfer layer channel may include:
the pattern transfer layer at the opening of the channel is isotropically etched, so as to obtain the widened pattern transfer layer channel.

It is to be noted that, in the present embodiment, the pattern transfer layer at the opening of the channel is isotropically etched, and the entire surface of the pattern transfer layer at the opening of the channel is etched. The specific manner of isotropically etching the pattern transfer layer at the opening of the channel is not limited in the present embodiment, as long as the widened pattern transfer layer channel can be obtained. For example, isotropic etching may use dry etching, or wet etching. Since the pattern transfer layer at the opening of the channel is isotropically etched in the present embodiment, the step of controlling the pattern transfer layer at the opening of the channel, so as to obtain the widened pattern transfer layer channel may be completed by controlling an etching time. In addition, in the present embodiment, the corresponding material for isotropic etching may be determined according to the material of the pattern transfer layer.

In some embodiments, in order to improve the ease of connection between a final bottom electrode structure and a memory cell, thereby improving the device performance of the memory chip, the above operation that the pattern transfer layer at the opening of the channel is isotropically etched, so as to obtain the widened pattern transfer layer channel may include:
the pattern transfer layer at the opening of the channel is isotropically etched until a first cross-sectional area of the widened pattern transfer layer channel is greater than a second cross-sectional area of the memory cell, and a difference between the first cross-sectional area and the second cross-sectional area reaches an area threshold, so as to obtain the widened pattern transfer layer channel. And the first cross-sectional area is a cross-sectional area of the widened pattern transfer layer channel, and the second cross-sectional area is a cross-sectional area of the memory cell.

It is to be noted that, when the first cross-sectional area of the widened pattern transfer layer channel is greater than the second cross-sectional area of the memory cell, the connection between the final bottom electrode structure and the memory cell is facilitated, thereby improving the alignment tolerance of the connection between the final bottom electrode structure and the memory cell.

The setting of the area threshold is not limited in the present embodiment. For example, the area threshold may be customized by an customer, or the area threshold may be set according to the second cross-sectional area of the memory cell, and the smaller the second cross-sectional area of the memory cell, the larger the set value of the area threshold.

At S103, a region to be widened in the bottom electrode dielectric layer is etched along the widened pattern transfer layer channel, so as to obtain a bottom electrode via structure which extends to the bottom circuit.

In the present embodiment, etching of the bottom electrode dielectric layer through the widened pattern transfer layer channel does not stop until the etching of the region to be widened in the bottom electrode dielectric layer is completed, and the shape of the widened pattern transfer layer channel is transferred to the bottom electrode dielectric layer. It is to be noted that, in the present embodiment, a depth of the region to be widened is less than the thickness of the bottom electrode dielectric layer, that is, in this example, only a part of the bottom electrode dielectric layer is etched along the widened pattern transfer layer channel, and not the entire channel in the bottom electrode dielectric layer is widened. The specific depth of the region to be widened is not limited in the present embodiment, as long as it is less than the thickness of the bottom electrode dielectric layer. For example, the depth of the region to be widened may be one-quarter, one-fifth, or one-third of the overall thickness of the bottom electrode dielectric layer. However, it is to be noted that, in the present embodiment, a depth of the channel apart from the region to be widened in the bottom electrode dielectric layer should be greater than an over-etching amount of the memory cell. The over-etching amount of the memory cell is defined the depth from an upper surface of the region to be widened to a lower surface at the lowest position of a memory cell protection layer.

In some embodiments, in order to facilitate the removal of metal re-deposition caused in the manufacturing of the memory cell, the depth of the region to be widened in the above bottom electrode dielectric layer may be less than an etching amount of the memory cell. The etching amount of the memory cell is defined the depth from an upper surface of the memory cell to a lower surface at the lowest position of the memory cell protection layer.

At S104, the bottom electrode via structure is filled with a bottom electrode material, so as to obtain the final bottom electrode structure.

In the present embodiment, the formed bottom electrode via structure is filled with the bottom electrode material, so as to obtain the final bottom electrode structure. It is to be noted that the specific material of the bottom electrode material is not limited in the present embodiment. For example, the specific material of the bottom electrode material may be a material obtained by depositing metal tungsten using Chemical Vapor Deposition (CVD), or other materials meeting the requirements, where CVD is chemical vapor deposition. It is to be noted that, in order to ensure the filling performance of the bottom electrode material, the bottom electrode material in the present embodiment may be compatible with a CMP process, and at the same time, the bottom electrode material may also have the characteristic of low surface roughness. The specific structure of the final bottom electrode structure is not limited in the present embodiment. For example, the specific structure of the final bottom electrode structure may be a structure with a T-shaped cross section, or an L-shaped structure with a cross section inverted in a vertical direction, or other structures.

At S105, a memory cell and a top circuit structure are manufactured on a surface of the final bottom electrode structure facing away from the bottom circuit, so as to obtain the memory chip. It is to be noted that, in the present embodiment, a memory cell protection layer may be provided outside the memory cell. Before the memory cell and the top circuit structure are manufactured on the surface of the final bottom electrode structure facing away from the bottom circuit, the pattern transfer layer needs to be completely removed.

In some embodiments, in order to improve the tightness of the connection between the final bottom electrode structure and the memory cell, thereby improving the device performance, before the above operation that the memory cell and the top circuit structure are manufactured on the surface of the final bottom electrode structure facing away from the bottom circuit, so as to obtain the memory chip, the method may further include:

CMP is performed on the surface of the final bottom electrode structure.

It is to be noted that, in the present embodiment, CMP is performed on the surface of the final bottom electrode structure, which can ensure that multiple bottom electrodes in the final bottom electrode structure are separated from each other, thereby preventing channel short circuits. In the present embodiment, the dielectric thickness loss due to CMP should be less than the depth of the region to be widened in the bottom electrode dielectric layer.

Applying the method for manufacturing the memory chip provided by the embodiments of the present disclosure, the surface of the pattern transfer layer in the structure to be etched is etched, so as to form the channel, where the channel extends to the bottom electrode dielectric layer in the structure to be etched, and the structure to be etched is the structure formed by sequential deposition of the bottom electrode dielectric layer and the pattern transfer layer on the surface of the bottom circuit. The pattern transfer layer at the opening of the channel is etched, so as to form the widened pattern transfer layer channel, and the region to be widened in the bottom electrode dielectric layer is etched along the widened pattern transfer layer channel, so as to obtain the bottom electrode via structure which extends to the bottom circuit, where the depth of the region to be widened is less than the thickness of the bottom electrode dielectric layer. The bottom electrode via structure is filled with the bottom electrode material, so as to form the final bottom electrode structure, and the memory cell and the top circuit structure are manufactured on the surface of the final bottom electrode structure facing away from the bottom circuit, so as to obtain the memory chip. In the present disclosure, an electrode structure including a widened part and a non-widened part is manufactured, and the widened part of the final bottom electrode structure is connected to the memory cell, so that the problem of an excessive area of metal caused by the manufacture of a flat buffer layer, which in turn causes unnecessary metal re-deposition and affects the device performance and yield, can be avoided, the complexity of a device manufacturing process is reduced, and the cost of device manufacturing is reduced. In addition, in the present disclosure, the depth of the channel extending to the bottom electrode dielectric layer is set to be less than the thickness of the bottom electrode dielectric layer, which can ensure that the surface of the bottom circuit cannot be contaminated in the etching process; the region to be widened in the bottom electrode dielectric layer and the bottom of the channel are simultaneously etched along the widened pattern transfer layer channel until the channel extends to the bottom circuit, so that the efficiency of memory chip manufacturing is improved, and the time cost of etching is reduced; the photoresist layer containing the lithographic channel is formed on the pattern transfer layer, and the channel is etched on the surface of the pattern transfer layer along the lithographic channel, so that the efficiency of etching the channel is improved, and the steps of etching the channel are simplified; the bottom electrode dielectric and the pattern transfer layer material are sequentially deposited on the surface of the bottom circuit, so as to obtain the bottom electrode dielectric layer and the pattern transfer layer, and the pattern transfer layer at the opening of the channel is isotropically etched, so as to obtain the widened pattern transfer layer channel, so that the efficiency of widening the channel at the pattern transfer layer is improved; the pattern transfer layer at the opening of the channel is isotropically etched until the first cross-sectional area of the widened pattern transfer layer channel is greater than the second cross-sectional area of the memory cell, and the difference between the first cross-sectional area and the second cross-sectional area reaches the area threshold, so that the ease of connection between the final bottom electrode structure and the memory cell is improved, thereby improving the device performance of the memory chip; and the depth of the region to be widened in the bottom electrode dielectric layer is set to be less than the etching amount of the memory cell, so that the removal of metal re-deposition caused in the manufacturing of the memory cell can be minimized.

A memory chip structure provided by the embodiments of the present disclosure is described below, and the memory chip structure described below is manufactured by the above method for manufacturing the memory chip, and may be referred to in correspondence with the method for manufacturing the memory chip described above.

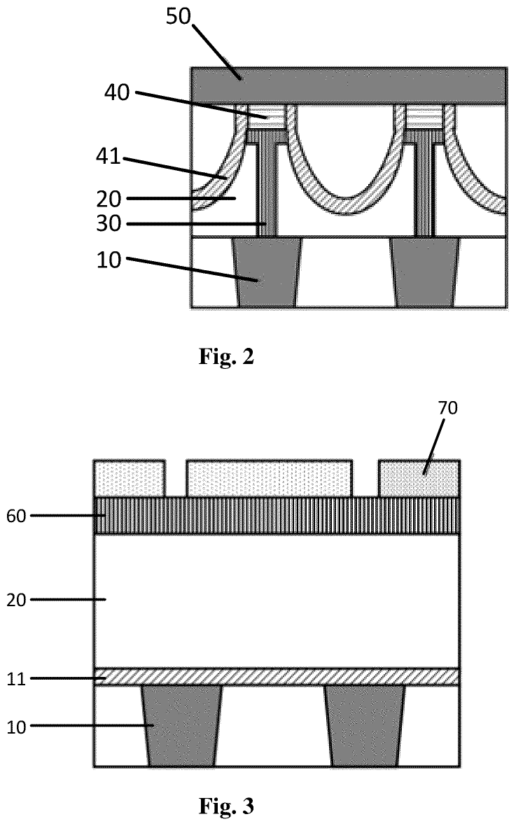

In some embodiments, referring to FIG. 2, FIG. 2 is a schematic diagram of a memory chip structure according to an embodiment of the present disclosure. The memory chip structure may include:
a bottom circuit 10, a bottom electrode dielectric layer 20, a final bottom electrode structure 30, a memory cell 40, and a top circuit structure 50.

The final bottom electrode structure 30 includes a widened part and a non-widened part. The non-widened part is connected to the bottom circuit 10, and the widened part is connected to the memory cell 40.

It is to be noted that, in the present embodiment, the widened part and the non-widened part in the final bottom electrode structure 30 are formed as a bottom electrode structure by integrally filling the bottom electrode material. In the present embodiment, the widened part is a region to be widened in the bottom electrode dielectric layer 20, specifically referring to FIG. 2.

In some embodiments, in order to improve the ease of connection between the final bottom electrode structure and the memory cell, thereby improving the device performance of a memory chip, a first cross-sectional area of the above widened part may be greater than a second cross-sectional area of the memory cell. It is to be noted that, in the present embodiment, a depth of a channel apart from the region to be widened in the bottom electrode dielectric layer 20 should be greater than an over-etching amount of the memory cell 40. The over-etching amount of the memory cell 40 is defined as the depth from an upper surface of the region to be widened to a lower surface at the lowest position of a memory cell protection layer 41.

In some embodiments, in order to facilitate the removal of metal re-deposition caused during the manufacturing of the memory cell 40, the depth of the region to be widened in the above bottom electrode dielectric layer 20 may be less than an etching amount of the memory cell 40. The etching amount of the memory cell 40 is defined as the depth from an upper surface of the memory cell 40 to a lower surface at the lowest position of the memory cell protection layer 41.

The memory chip structure provided by the embodiments of the present disclosure includes the bottom circuit 10, the bottom electrode dielectric layer 20, the final bottom electrode structure 30, the memory cell 40, and the top circuit structure 50. The final bottom electrode structure 30 includes the widened part and the non-widened part. The non-widened part is connected to the bottom circuit 10, and the widened part is connected to the memory cell 40. In the present disclosure, an electrode structure including the widened part and the non-widened part is manufactured, and the widened part of the final bottom electrode structure is connected to the memory cell, so that the problem of an excessive area of metal caused by the need to manufacture the flat buffer layer, which in turn causes unnecessary metal re-deposition and affects the device performance and yield, can be avoided, the complexity of a device manufacturing process is reduced, and the cost of device manufacturing is reduced. In addition, the first cross-sectional area of the widened part is set to be greater than the second cross-sectional area of the memory cell, so that the ease of connection between the final bottom electrode structure and the memory cell is improved, thereby improving the device performance of the memory chip; and the depth of the region to be widened in the bottom electrode dielectric layer is set to be less than the etching amount of the memory cell, so that the removal of metal re-deposition caused during the manufacturing of the memory cell can be minimized.

In order to facilitate the understanding of the present disclosure, a method for manufacturing a memory chip in the present disclosure may specifically include the following steps.

At S1, the bottom circuit diffusion barrier layer 11, the bottom electrode dielectric layer 20, and the pattern transfer layer 60 are sequentially deposited on the bottom circuit 10, and the photoresist layer 70 containing the lithographic channel is formed on the surface. Specifically, referring to FIG. 3, FIG. 3 is a schematic structure of step S1 of the method for manufacturing the memory chip according to an embodiment of the present disclosure.

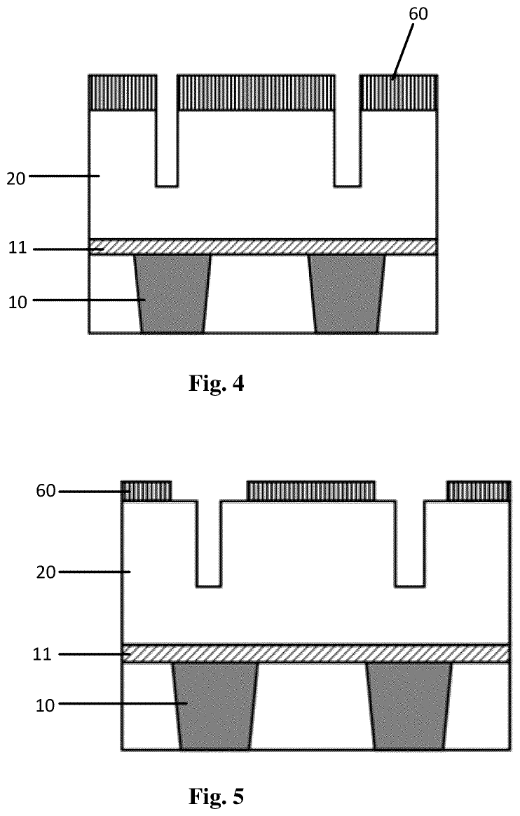

At S2, the channel is etched on the surface of the pattern transfer layer 60 along the above lithographic channel, and extends into the bottom electrode dielectric layer 20, and the depth of the channel extending to the bottom electrode dielectric layer 20 is less than the thickness of the bottom electrode dielectric layer 20. The photoresist layer 70 is completely removed. Specifically, referring to FIG. 4, FIG. 4 is a schematic structure of step S2 of the method for manufacturing the memory chip according to an embodiment of the present disclosure.

At S3, the pattern transfer layer 60 at the opening of the channel is isotropically etched until the first cross-sectional area of the widened pattern transfer layer channel is greater than the second cross-sectional area of the memory cell 40, and the difference between the first cross-sectional area and the second cross-sectional area reaches the area threshold, so as to obtain the widened pattern transfer layer channel. Specifically, referring to FIG. 5, FIG. 5 is a schematic structure of step S3 of the method for manufacturing the memory chip according to an embodiment of the present disclosure.

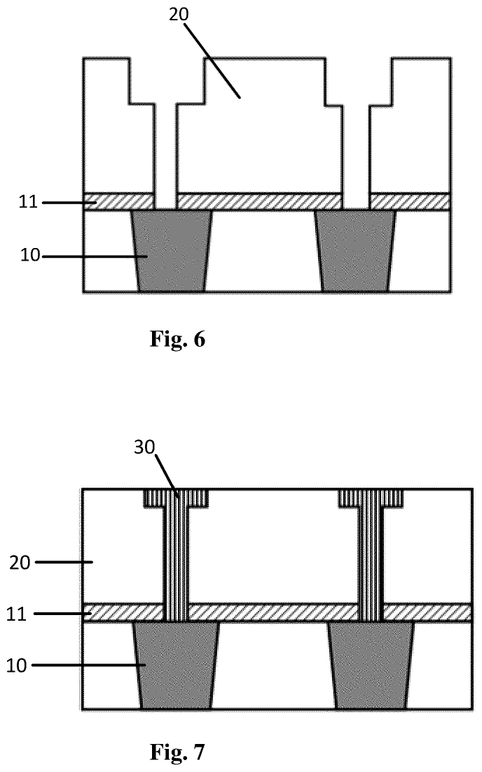

At S4, the region to be widened in the bottom electrode dielectric layer 20 and the bottom of the channel are simultaneously etched along the widened pattern transfer layer channel until the channel extends to the bottom circuit 10, so as to obtain the bottom via structure, and the pattern transfer layer material is completely removed. Specifically, referring to FIG. 6, FIG. 6 is a schematic structure of step S4 of the method for manufacturing the memory chip according to an embodiment of the present disclosure. The depth of the region to be widened in the above bottom electrode dielectric layer 20 is less than the etching amount of the memory cell, and the depth of the channel apart from the region to be widened in the bottom electrode dielectric layer is greater than the over-etching amount of the memory cell.

At S5, the bottom electrode via structure is filled with the bottom electrode material, and CMP is performed to separate the bottom electrodes from each other, so as to obtain the final bottom electrode structure 30. Specifically, referring to FIG. 7, FIG. 7 is a schematic structure of step S5 of the method for manufacturing the memory chip according to an embodiment of the present disclosure.

At S6, the memory cell 40 and the top circuit structure 50 are manufactured on the surface of the final bottom electrode structure 30 facing away from the bottom circuit 10, so as to obtain the memory chip. Specifically, referring to FIG. 2, FIG. 2 is a schematic diagram of the memory chip structure according to an embodiment of the present disclosure.

It is to be noted that, in the present embodiment, the depth of the channel apart from the region to be widened in the bottom electrode dielectric layer 20 is greater than the over-etching amount of the memory cell 40. The over-etching amount of the memory cell 40 is the depth from the upper surface of the region to be widened to the lower surface at the lowest position of the memory cell protection layer 41. In order to facilitate the removal of metal re-deposition caused during the manufacturing of memory cell 40, the depth of the region to be widened in the above bottom electrode dielectric layer 20 is less than the etching amount of the memory cell 40. The etching amount of the memory cell 40 is the depth from the upper surface of the memory cell 40 to the lower surface at the lowest position of the memory cell protection layer 41.

The various embodiments in the present specification are described in a progressive manner, and each embodiment focuses on differences from other embodiments, and the same or similar parts between the various embodiments may be referred to each other. For the apparatus disclosed in the embodiment, since it corresponds to the method disclosed in the embodiment, the description is relatively simple, and the relevant parts can be referred to the method part.

Professionals may realize that the units and algorithm steps of each example described in combination with the embodiments disclosed in the present disclosure may be implemented by electronic hardware, computer hardware or a combination of computer software and the electronic hardware. In order to clearly illustrate the interchangeability of hardware and software, the composition and steps of each example have been described in general terms of function in the above description. Whether these functions are executed in a hardware or software manner depends on specific applications and design constraints of the technical solutions. Professionals may realize the described functions for each specific application by use of different methods, but such realization shall fall within the scope of the present disclosure.

Finally, it is to be noted that relational terms such as first, second, and the like herein are adopted only to distinguish one entity or operation from another entity or operation and not always to require or imply existence of any such practical relationship or sequence between the entities or operations. Furthermore, terms “include” and “contain” or any variant thereof is intended to cover nonexclusive inclusions herein, so that a process, method, object or device including a series of elements not only includes those elements but also includes other elements which are not clearly listed or further includes elements intrinsic to the process, the method, the object or the device.

The method for manufacturing the memory chip and the memory chip structure provided in the present disclosure are described in detail above. The principles and implementations of the present disclosure are described herein using specific examples, the description of the above embodiments are only used to help the understanding of the method and core concept of the present disclosure. At the same time, for those of ordinary skill in the art, according to the concept of the present disclosure, there will be changes in the specific implementations and the application scope. In summary, the contents of the present description should not be construed as limiting the present disclosure.

What is claimed is:

1. A method for manufacturing a memory chip, comprising:
etching a surface of a pattern transfer layer in a structure to be etched, so as to form a channel, wherein the channel extends to a bottom electrode dielectric layer in the structure to be etched, and the structure to be etched is a structure formed by sequential deposition of the bottom electrode dielectric layer and the pattern transfer layer on a surface of a bottom circuit;
etching the pattern transfer layer at an opening of the channel, so as to obtain a widened pattern transfer layer channel;
etching, along the widened pattern transfer layer channel, a region to be widened in the bottom electrode dielectric layer, so as to obtain a bottom electrode via structure which extends to the bottom circuit, wherein a depth of the region to be widened is less than a thickness of the bottom electrode dielectric layer;
filling the bottom electrode via structure with a bottom electrode material, so as to obtain a final bottom electrode structure; and
manufacturing a memory cell and a top circuit structure on a surface of the final bottom electrode structure facing away from the bottom circuit, so as to obtain the memory chip.

2. The method for manufacturing the memory chip as claimed in claim 1, wherein a depth of the channel extending to the bottom electrode dielectric layer is less than the thickness of the bottom electrode dielectric layer.

3. The method for manufacturing the memory chip as claimed in claim 2, wherein etching, along the widened pattern transfer layer channel, the region to be widened in the bottom electrode dielectric layer, so as to obtain the bottom electrode via structure which extends to the bottom circuit comprises:
simultaneously etching, along the widened pattern transfer layer channel, the region to be widened in the bottom electrode dielectric layer and a bottom of the channel until the channel extends to the bottom circuit, so as to obtain the bottom electrode via structure.

4. The method for manufacturing the memory chip as claimed in claim 2, wherein the etching the surface of the pattern transfer layer in the structure to be etched, so as to form the channel comprises:
manufacturing a photoresist layer containing a lithographic channel on the pattern transfer layer; and
etching, along the lithographic channel, the surface of the pattern transfer layer to obtain the channel.

5. The method for manufacturing the memory chip as claimed in claim 1, wherein etching the pattern transfer layer at the opening of the channel, so as to obtain the widened pattern transfer layer channel comprises:
isotropically etching the pattern transfer layer at the opening of the channel, so as to obtain the widened pattern transfer layer channel.

6. The method for manufacturing the memory chip as claimed in claim 5, wherein isotropically etching the pattern transfer layer at the opening of the channel, so as to obtain the widened pattern transfer layer channel comprises:
isotropically etching the pattern transfer layer at the opening of the channel until a first cross-sectional area of the widened pattern transfer layer channel is greater than a second cross-sectional area of the memory cell, and a difference between the first cross-sectional area and the second cross-sectional area reaches an area threshold, so as to obtain the widened pattern transfer layer channel.

7. The method for manufacturing the memory chip as claimed in claim 1, wherein the depth of the region to be widened in the bottom electrode dielectric layer is less than an over etching dielectric loss of the memory cell.

8. The method for manufacturing the memory chip as claimed in claim 1, wherein, before etching the surface of the pattern transfer layer in the structure to be etched, so as to form the channel, the method further comprises:
sequentially deposit a bottom electrode dielectric and a pattern transfer layer material on the surface of the bottom circuit, so as to obtain the bottom electrode dielectric layer and the pattern transfer layer; and
using a structure composed of the bottom circuit, the bottom electrode dielectric layer, and the pattern transfer layer as the structure to be etched.

9. A memory chip structure, manufactured using the method for manufacturing the memory chip as claimed in claim 1, wherein the memory chip structure comprises:
the bottom circuit, the bottom electrode dielectric layer, the final bottom electrode structure, the memory cell, and the top circuit structure;
wherein the final bottom electrode structure comprises a widened part and a non-widened part, the non-widened part is connected to the bottom circuit, and the widened part is connected to the memory cell.

10. The memory chip structure as claimed in claim 9, wherein a first cross-sectional area of the widened part is greater than a second cross-sectional area of the memory cell.

11. The method for manufacturing the memory chip as claimed in claim 8, wherein, before sequential deposition of the bottom electrode dielectric and the pattern transfer layer material on the surface of the bottom circuit, so as to obtain the bottom electrode dielectric layer and the pattern transfer layer, the method further comprises:
providing a bottom circuit diffusion barrier layer on the surface of the bottom circuit.

12. The method for manufacturing the memory chip as claimed in claim 1, wherein etching the pattern transfer layer at the opening of the channel, so as to obtain the widened pattern transfer layer channel comprises:
performing lateral etching on the opening of the channel of the pattern transfer layer, so as to obtain the widened pattern transfer layer channel.

13. The method for manufacturing the memory chip as claimed in claim 1, wherein etching the pattern transfer layer at the opening of the channel, so as to obtain the widened pattern transfer layer channel comprises:
covering certain part of the pattern transfer layer with a photoresist, and performing etching at a position exposing the opening of the channel of the pattern transfer layer, so as to obtain the widened pattern transfer layer channel.

14. The method for manufacturing the memory chip as claimed in claim 5, wherein isotropically etching the pattern transfer layer at the opening of the channel, so as to obtain the widened pattern transfer layer channel comprises:
etching the pattern transfer layer at the opening of the channel using an isotropic dry etching method, so as to obtain the widened pattern transfer layer channel.

15. The method for manufacturing the memory chip as claimed in claim 5, wherein isotropically etching the pattern transfer layer at the opening of the channel, so as to obtain the widened pattern transfer layer channel comprises:
etching the pattern transfer layer at the opening of the channel using an isotropic wet etching method, so as to obtain the widened pattern transfer layer channel.

16. The method for manufacturing the memory chip as claimed in claim 1, wherein, after manufacturing the memory cell on the surface of the final bottom electrode structure facing away from the bottom circuit, the method further comprises: providing a memory cell protection layer outside the memory cell; and
before manufacturing the memory cell and the top circuit structure on the surface of the final bottom electrode structure facing away from the bottom circuit, the method further comprises: completely removing the pattern transfer layer.

17. The method for manufacturing the memory chip as claimed in claim 16, wherein a depth of the channel in the bottom electrode dielectric layer apart fromfor the region to be widened is greater than an over-etching amount of the memory cell, wherein the over-etching amount of the memory cell is a depth from an upper surface of the region to be widened to a lower surface at a lowest position of the memory cell protection layer.

18. The method for manufacturing the memory chip as claimed in claim 1, wherein filling the bottom electrode via structure with the bottom electrode material, so as to obtain the final bottom electrode structure comprises:
depositing metal tungsten in the bottom electrode via structure using Chemical Vapor Deposition (CVD), so as to obtain the final bottom electrode structure.

19. The method for manufacturing the memory chip as claimed in claim 1, wherein a cross section of the final bottom electrode structure is one of following: a T-shaped structure and an L-shaped structure inverted in a vertical direction.

20. The method for manufacturing the memory chip as claimed in claim 1, wherein, before manufacturing the memory cell and the top circuit structure on the surface of the final bottom electrode structure facing away from the bottom circuit, so as to obtain the memory chip, the method further comprises:
performing Chemical Mechanical Polishing (CMP) on the surface of the final bottom electrode structure.
